(19) United States
(12) Patent Application Publication
(10) Pub. No.: US 2026/0129941 A1
(43) Pub. Date: May 7, 2026

(54) BACKSIDE CONTACTS

(71) Applicant: Taiwan Semiconductor Manufacturing Company, Ltd., Hsinchu (TW)

(72) Inventors: Yung-Ting Chang, New Taipei City (TW); Jui-Lin Chen, Taipei City (TW); Cheng-Ming Lee, Taoyuan County (TW); Shih-Chieh Wu, Hsinchu (TW)

(21) Appl. No.: 19/060,346

(22) Filed: Feb. 21, 2025

Related U.S. Application Data
(60) Provisional application No. 63/715,089, filed on Nov. 1, 2024.

(51) Int. Cl. H10D 64/23; H10B 10/00; H10D 30/00; H10D 30/01; H10D 30/43; H10D 62/10; H10D 84/01; H10D 84/83

(52) U.S. Cl. CPC H10D 64/251; H10B 10/12; H10D 30/014; H10D 30/0191; H10D 30/43; H10D 30/502; H10D 62/121; H10D 84/013; H10D 84/0149; H10D 84/0151; H10D 84/832

(57) ABSTRACT

A semiconductor structure according to the present disclosure includes a backside metal line and a backside contact structure that includes a bar portion disposed on the backside metal line, a first via extending from the bar portion, a second via extending from the bar portion, and a protrusion disposed between the first via and the second via. The semiconductor structure also includes a first source/drain feature over the first via, a second source/drain feature over the second via, and a gate isolation feature disposed between the first via and the second via. The protrusion extends into the gate isolation feature.

### PRIORITY DATA

This application claims priority to U.S. Provisional Patent Application Ser. No. 63/715,089, filed Nov. 1, 2024, the entirety of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Static random access memory (“SRAM”) generally refers to any memory or storage that can retain stored data only when power is applied. As integrated circuit (IC) technologies progress towards smaller technology nodes, multi-gate structures, such as fin-like field effect transistors (FinFETs) or gate-all-around (GAA) transistors, are integrated into SRAM cells to enhance performance. As dimensions of SRAM cells continue to shrink, the contact structures that functionally interconnect the transistors in SRAM cells present additional challenges in reduction of resistance (R) and capacitance (C).

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a circuit schematic of an SRAM cell according to various aspects of the present disclosure.

FIG. 2 is a top view of an SRAM cell, according to various aspects of the present disclosure.

FIG. 3 is a fragmentary top view of a frontside interconnect structure of an SRAM quad-cell, according to various aspects of the present disclosure.

FIG. 4 is fragmentary cross-sectional view along cross section A-A′ in FIG. 3, according to various aspects of the present disclosure.

FIG. 5 is a fragmentary top view of a backside interconnect structure of an SRAM quad-cell, according to various aspects of the present disclosure.

FIG. 6 is fragmentary cross-sectional view along cross section B-B′ in FIG. 5, according to various aspects of the present disclosure.

FIG. 7 is fragmentary cross-sectional view of a backside joint contact along cross section C-C′ in FIG. 5, according to various aspects of the present disclosure.

FIG. 8 includes a flowchart of method 300 for forming the backside joint contact, according to one or more aspects of the present disclosure.

FIGS. 9-19 illustrate fragmentary cross-sectional views a precursor structure going through various steps of the method 300 in FIG. 8, according to various aspects of the present disclosure.

FIG. 20 illustrates a fragmentary cross-sectional view of a semiconductor structure where a jut portion of a backside joint contact overhangs a backside metal line, according to various aspects of the present disclosure.

FIG. 21 illustrates a fragmentary top view of a backside interconnect structure of an SRAM quad-cell having the backside joint contact in FIG. 20, according to various aspects of the present disclosure.

FIG. 22 illustrates a fragmentary cross-sectional view of a semiconductor structure where jut portions of a backside joint contact overhang a backside metal line, according to various aspects of the present disclosure.

FIG. 23 illustrates a fragmentary top view of a backside interconnect structure of an SRAM quad-cell having the backside joint contact in FIG. 22, according to various aspects of the present disclosure.

FIG. 24 illustrates a fragmentary cross-sectional view of a semiconductor structure where the backside joint contact merges with a frontside common contact, according to various aspects of the present disclosure.

FIG. 25 illustrates a fragmentary top view of a backside interconnect structure of an SRAM quad-cell having the backside joint contact in FIG. 24, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. When describing aspects of a transistor, source/drain region(s) may refer to a source or a drain, individually or collectively, dependent upon the context.

Static Random Access Memory (SRAM) is a semiconductor memory that retains data in a static form as long as the memory has power. Compared to dynamic RAM (DRAM), SRAM is faster and more reliable and does not need to be refreshed. SRAM is widely used in many applications, such as a computer's cache memory and as part of the random access memory of digital-to-analog converter on a video card. As integrated circuit (IC) technologies progress towards smaller technology nodes, multi-gate structures, such as fin-like field effect transistors (FinFETs) or gate-all-around (GAA) transistors, are integrated into SRAM cells to enhance performance. The shrinkage in dimensions presents stress on electrical routing. When only a frontside interconnect structure is present, contact via and metal lines are tightly spaced and the frontside connections to various transistor nodes in an SRAM cell may exhibit high resistance. The tight spacing and the high contact resistance may lead to high resistance and capacitance, which may lead to low drive current and slow speed.

The present disclosure provides SRAM devices that include not only a frontside interconnect but also a backside interconnect to improve performance of SRAM devices. In one embodiment, sources of pull-down transistors are coupled to a backside ground rail by way of a backside joint contact to improve pull-down current. The backside joint contact includes a bar portion interfacing a backside metal line, a first via and a second via extending from the bar portion toward source features, and a protrusion disposed between the first via and the second via. The bar portion, the first via, the second via, and the protrusion in the middle give the backside joint contact a shape like the letter M. The shape of the backside joint contact is a result of structures surrounding the backside joint contact and an etch process that etches silicon, silicon nitride, and silicon oxide at different rates. The formation of the backside joint contact enlarges the backside via etch process window and reduces contact resistance.

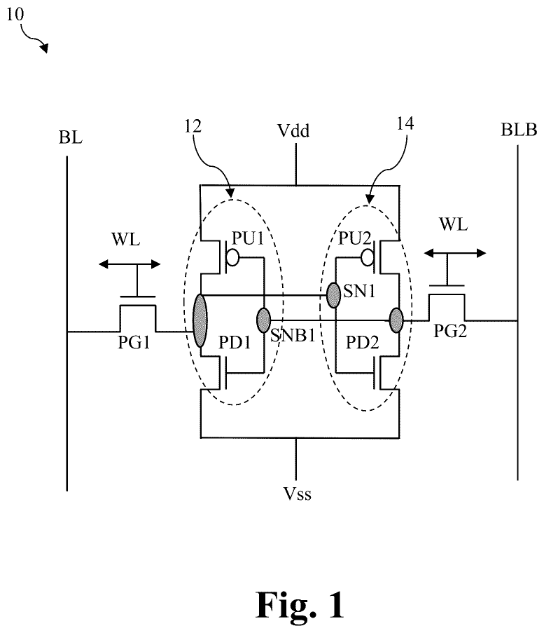

FIG. 1 illustrates an example type of memory device in which transistors such as planar transistors, FinFET transistors, or gate-all-around (GAA) transistors may be implemented. In that regard, FIG. 1 illustrates the circuit schematic of an example SRAM device, for example, as a single-port SRAM cell (e.g., 1-bit SRAM cell) 10. The single-port SRAM cell 10 includes first and second pass-gate transistors PG1 and PG2, first and second pull-up transistors PU1 and PU2, and first and second pull-down transistors PD1 and PD-2. The gates of the first and second pass-gate transistors PG1 and PG2 are electrically coupled to word-line (WL) that determines whether the SRAM cell 10 is selected or not. In the SRAM cell 10, a memory bit (e.g., a latch or a flip-flop) is formed of the first and second pull-up transistors PU1 and PU2 and the first and second pull-down transistors PD1 and PD2 to store a bit of data. The complementary values of the bit are stored in a first storage node SN1 and a first complementary storage node SNB1. The stored bit can be written into, or read from, the SRAM cell 10 through Bit-line (BL) and Bit-Line Bar (BLB). In this arrangement, the BL and BLB may carry complementary bit-line signals. The SRAM cell 10 is powered through a positive power supply voltage Ved and is also connected to a ground potential Vss.

The SRAM cell 10 includes a first inverter 12 formed of the first pull-up transistor PU1 and the first pull-down transistor PD1 as well as a second inverter 14 formed of the second pull-up transistor PU2 and the second pull-down transistor PD2. As shown in FIG. 1, drains of the first pull-up transistor PU1 and the first pull-down transistor PD1 are coupled together and drains of the second pull-up transistor PU2 and the second pull-down transistor PD2 are coupled together. The first inverter 12 and the second inverter 14 are coupled between the positive supply voltage Vdd and the ground potential Vss. As shown in FIG. 1, the first inverter 12 and the second inverter 14 are cross-coupled. That is, the first inverter 12 has an input coupled to the output of the second inverter 14. Likewise, the second inverter 14 has an input coupled to the output of the first inverter 12. The output of the first inverter 12 is referred to as the first storage node SN1. Likewise, the output of the second inverter 14 is referred to as the first complementary storage node SNB1. In a normal operating mode, the first storage node SN1 is in the opposite logic state (logic high or logic low) as the first complementary storage node SNB1. By employing the two cross-coupled inverters, the SRAM cell 10 can hold the data using a latched structure so that the stored data will not be lost without applying a refresh cycle as long as power is supplied through Vdd.

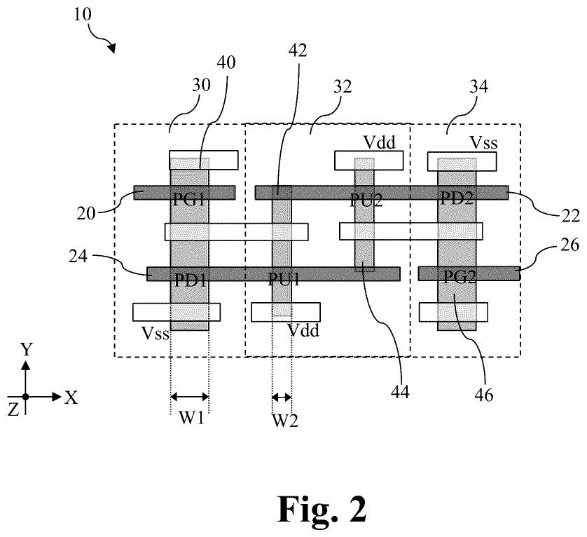

Referring now to FIG. 2, shown therein is an example layout of the SRAM cell 10 in FIG. 1. Like the SRAM cell 10 in FIG. 1, the layout in FIG. 2 includes six (6) transistors functioning as the first pass-gate transistor PG1, the second pass-gate transistor PG2, the first pull-up transistor PU1, the second pull-up transistor PU2, the first pull-down transistor PD1, and the second pull down transistor PD2. In some implementations represented in FIG. 2, the SRAM cell 10 may be formed over an n-type well 32 (or N well 32) sandwiched between two p-type wells 30 and 34 (or P wells 30 and 34). The N well 32 and P wells 30, 34 are formed over a substrate. In some embodiments, as shown in FIG. 2, the first pass-gate transistor PG1, the first pull-down transistor PD1, the second pull-down transistor PD2, and the second pass-gate transistor PG2 may be formed over the P wells 30 and 34; and the first pull-up transistor PU1 and the second pull-up transistor PU2 are formed in the N well 32. In these embodiments, the first pass-gate transistor PG1, the first pull-down transistor PD1, the second pull-down transistor PD2, and the second pass-gate transistor PG2 are n-type GAA transistors; and the first pull-up transistor PU1 and the second pull-up transistor PU2 are p-type GAA transistors.

In some embodiments, the SRAM cell 10 includes four fin-shaped vertical stacks - a first fin-shaped vertical stack 40, a second fin-shaped vertical stack 42, a third fin-shaped vertical stack 44, and a fourth fin-shaped vertical stack 46. The first fin-shaped vertical stack 40 is formed over the P well 30 and forms the channel regions of the first pass-gate transistor PG1 and the first pull-down transistor PD1. The second fin-shaped vertical stack 42 and third fin-shaped vertical stack 44 are formed over the N well 32 and form the channel regions of the first pull-up transistor PU1 and the second pull-up transistor PU2, respectively. The fourth fin-shaped vertical stack 46 is formed over the P well 34 and forms the channel regions of the second pull-down transistor PD2 and the second pass-gate transistor PG2. Each of the first, second, third, and fourth fin-shaped vertical stacks 40, 42, 44, and 46 may include about two (2) to about ten (10) channel members. In some embodiments, each of the first, second, third, and fourth fin-shaped vertical stacks 40, 42, 44, and 46 includes 3 channel members. Each of the first, second, third, and fourth fin-shaped vertical stacks 40, 42, 44, and 46 may be referred to as an active region.

In some instances, the fin-shaped vertical stacks may be formed by depositing or epitaxially growing alternating layers of two different semiconductor materials, patterning the alternating layers to form fin-shaped structures, and selectively removing layers formed of one of the two semiconductor materials. For example, alternating layers of epitaxially grown silicon (Si) and silicon germanium (SiGe) can be formed on a substrate. The substrate may be a silicon (Si) substrate. The alternating layers may then be patterned to form fin-shaped structures that include stacks of interleaved Si strips and SiGe stripes. In processes to form a channel region of a transistor in a SRAM cell, the channel region of the fin-shaped structures may undergo different etching processes to selectively remove the SiGe strips, releasing silicon layers as suspended silicon channel members. The channel members may assume different shapes and dimensions and may be referred to as nanostructure, nanowires, or nanosheets. These fin-shaped structures are separated by an isolation feature, such as a shallow trench isolation (STI) feature. In some implementations, each of the fin-shaped vertical stacks may include a top portion formed from the alternating layers and a base portion formed from the substrate. The base portions of the fin-shaped vertical stacks have a shape of a fin and may be referred to as fin structures. The base portions of the fin-shaped vertical stacks may be substantially buried in the isolation feature and top ends of the base portions of the fin-shaped vertical stacks may be level with a top surface of the isolation feature. The top portions of the fin-shaped vertical stacks extend from and rise above the isolation feature.

Reference is still made to FIG. 2. The channel members in the first fin-shaped vertical stack 40 form channel regions of the first pass-gate transistor PG1 and the first pull-down transistor PD1. The channel members in the second fin-shaped vertical stack 42 form channel regions of the first pull-up transistor PU1. The channel members in the third fin-shaped vertical stack 44 form channel regions of the second pull-up transistor PU2. The channel members in the fourth fin-shaped vertical stack 46 form channel regions of the second pull-down transistor PD2 and the second pass-gate transistor PG2. In the depicted embodiments, the first fin-shaped vertical stack 40 and the fourth fin-shaped vertical stack 46 are used to form n-type GAA transistors and the second fin-shaped vertical stack 42 and the third fin-shaped vertical stack 44 are used to form p-type GAA transistors. In the embodiments illustrated in FIG. 2, the first pass-gate transistor PG1, the first pull-down transistor PD1, the second pass-gate transistor PG2, the second pull-down transistor PD2 are n-type GAA transistors, and the first pull-up transistor PU1 and the second pull-up transistor PU-2) are p-type GAA transistors. In FIG. 2, each of the first fin-shaped vertical stack 40 and fourth fin-shaped vertical stack 46 has a first width W1 along the X direction and each of the second fin-shaped vertical stack 42 and the third fin-shaped vertical stack 44 has a second width W2 along the X direction. In some embodiments, in order to achieve better read/write performance, the n-type GAA transistors have greater channel widths than the p-type GAA transistors. That is, the first width W1 may be greater than the second width W2. In some instances, a ratio of the first width W1 to the second width W2 (W1/W2) is between about 1 and about 5, including between about 1.1 and about 3.0.

As illustrated in FIG. 2, a channel of the first pass-gate transistor PG1 is controlled by a gate structure 20, channels of the first pull-down transistor PD1 and the first pull-up transistor PU1 are controlled by a gate structure 24, channels of the second pull-down transistor PD2 and the second pull-up transistor PU2 are controlled by a gate structure 22, and a channel of the second pass-gate transistor PG2 is controlled by a gate structure 26. As the gate structures 20 and 22 are segmented from a single gate structure, they are aligned lengthwise along the X direction. As the gate structures 24 and 26 are segmented from a single gate structure, they are aligned lengthwise along the X direction. The first fin-shaped vertical stack 40, the second fin-shaped vertical stack 42, the third fin-shaped vertical stack 44, and the fourth fin-shaped vertical stack 46 extend lengthwise along the Y direction, perpendicular to the X direction. In circuit and physical design, the SRAM cell 10 shown in FIG. 2 may serve as a repeating unit in an SRAM array. For ease of signal routing, adjacent SRAM cells 10 in an SRAM array may be mirror images of one another along their borders.

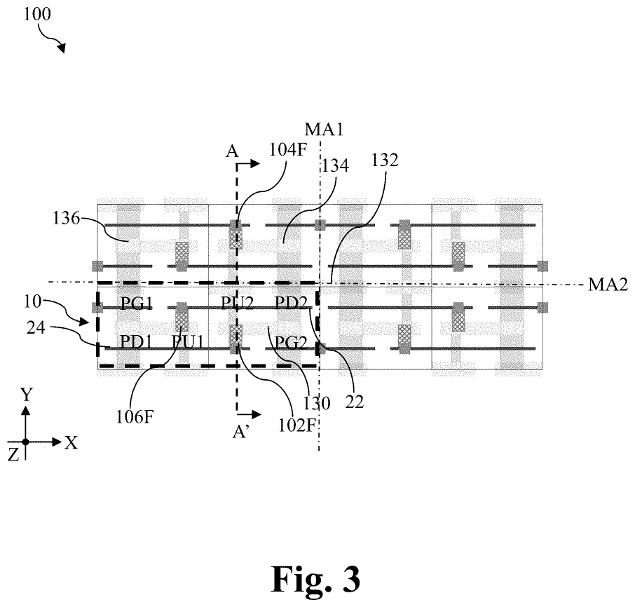

FIGS. 3-7 illustrate various aspects of an example embodiment where sources of second pull-down transistors PD2 of multiple SRAM cells are electrically coupled to a backside metal line by way of a backside joint contact. With respect to this example embodiment, FIG. 3 illustrates a frontside top view of a quad-cell 100 that includes 4 SRAM cells 10. An SRAM cell 10 is shown in FIG. 3 as a dotted rectangular box. For illustration purposes, FIG. 3 also includes a first mirror axis MA1, which extends along the Y direction and a second mirror axis MA2, which extends along the X direction. It can be seen that the SRAM cell across the first mirror axis MA1 from the SRAM cell 10 is a mirror image of the SRAM cell 10. Similarly, the SRAM cell across the second mirror axis MA2 from the SRAM cell is a mirror image of the SRAM cell 10. The mirror imaging configuration allows merging of the pull-up transistors, the pull-down transistors, and pass-gate transistors for efficient routing and electrical connection. On the front side, a frontside interconnect layer in FIG. 3 include butted contacts, such as a first frontside butted contact 102F, a second frontside butted contact 104F, and a third frontside butted contact 106F. The first frontside butted contact 102F couples a gate structure 24 of the first pull-up transistor PU1 to a source of the second pull-up transistor PU2. In the SRAM cell above the SRAM cell 10, the second frontside butted contact 104F also couples a gate structure of the first pull-up transistor PU1 to a source of the second pull-up transistor PU2. The third frontside butted contact 106F couples the gate structure 22 of the second pull-up transistor PU2 to the source of the first pull-up transistor PU1. FIG. 3 also shows a first common contact 130 that couples together drains of the second pull-up transistor PU2 and the second pull-down transistor PD2, a second common contact 132 that couples together sources of two adjacent pull-down transistors, a third common contact 134 couples together drains of a pull-up transistor and a pull-down transistor, and fourth common contact 136 that couples together sources of a pull-up transistor and a pull-down transistor.

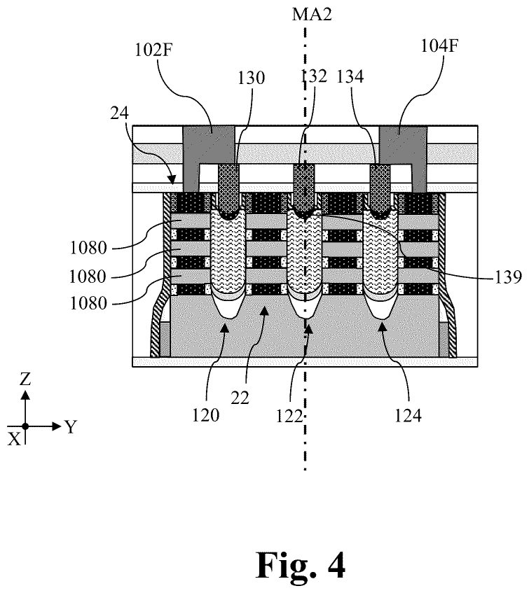

FIG. 4 illustrates a fragmentary cross-sectional view along cross section A-A′ in FIG. 3. As shown in FIG. 4, cross section A-A′ cuts through the gate structure 24, the gate structure 22, a gate structure that is a mirror image of the gate structure 22 (with respect to the second mirror axis MA2), and a gate structure that is a mirror image of the gate structure 24 (with respect to the second mirror axis MA2), the first common contact 130, the second common contact 132, and the third common contact 134, the first frontside butted contact 102F, the second frontside butted contact 104F, source 120 of the second pull-up transistor PU2, drain 122 of the second pull-up transistor PU2, and source 124 of the pull-up transistor in the SRAM cell over the SRAM cell 10. FIG. 4 also illustrates that the frontside interconnect layer is disposed above the transistors and the backside interconnect layer is disposed below the transistors. FIG. 4 illustrates stacks of channel members 1080 in different active regions and how each of the gate structures, such as the gate structure 22, wraps around each of the channel members 1080. FIG. 4 also illustrates how end walls of the channel members 1080 interface source/drain features, such as the source 120, drain 122 and the source 124. In some embodiments, the channel members 1080 include silicon (Si). The first common contact 130, the second common contact 132, and the third common contact 134 may include titanium (Ti), tungsten (W), ruthenium (Ru), cobalt (Co), nickel (Ni), or a combination thereof. In the depicted embodiments, the first common contact 130, the second common contact 132, and the third common contact 134 interface respective source or drain by way of a silicide layer 139. In some embodiments, the silicide layer 139 may include titanium silicide, cobalt silicide, or nickel silicide. In terms of electrical conductivity, an electrical conductivity of the second common contact 132 is greater than that of the silicide layer 139, which is more electrically conductive than the source 137 or the source 138.

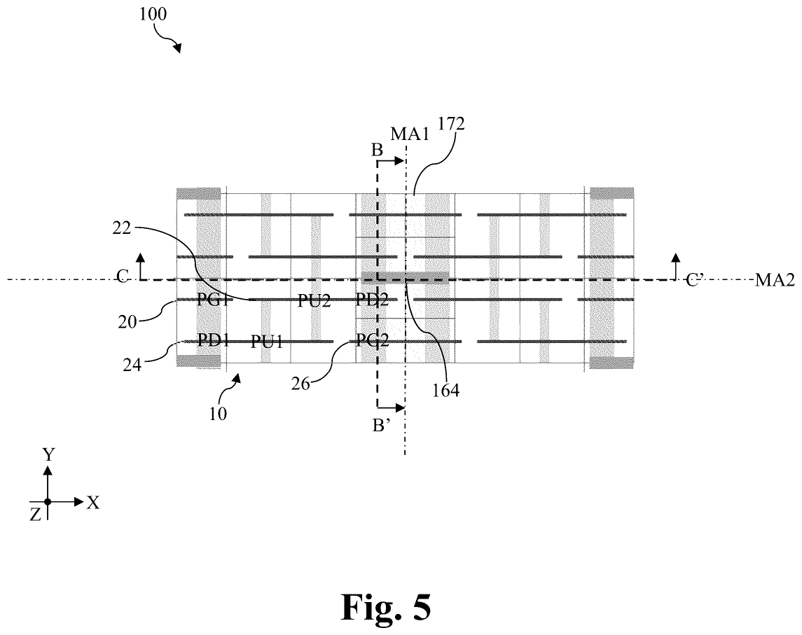

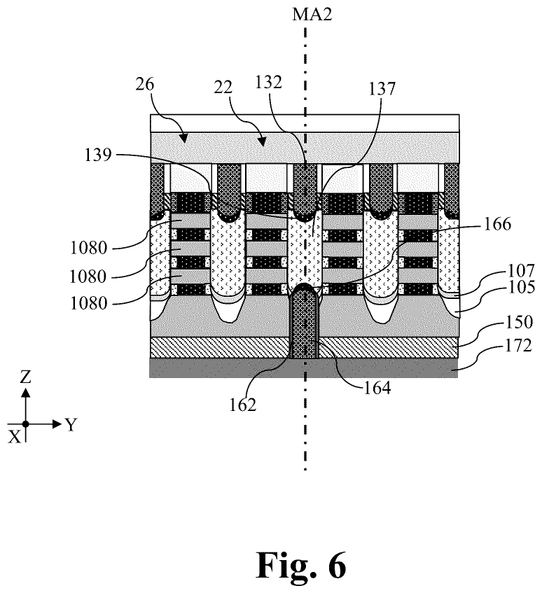

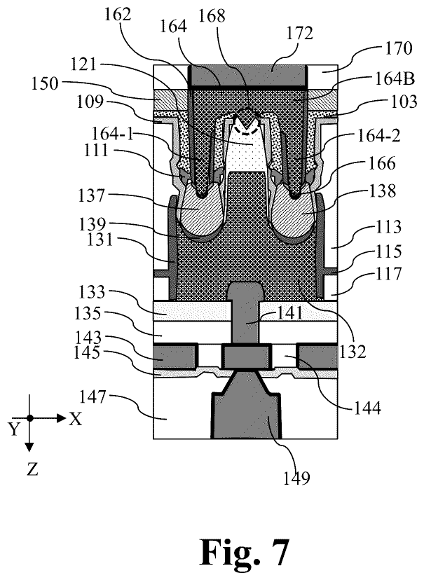

FIG. 5 illustrates a backside top view of the quad-cell 100. FIG. 5 illustrates a backside joint contact 164. The backside joint contact 164 connects source of second pull-down transistors (including the second pull-down transistor PD2) to a backside metal line 172. As shown in FIG. 5, the backside joint contact 164 directly land on the backside metal line 172. It is noted that sources of the first pull-up transistor PU1, the second pull-up transistor PU2, the first pass-gate transistor PG1, and the second pass-gate transistor PG2 are not coupled to any conductive features in the backside interconnect layer by way of any counterpart of the backside joint contact 164. FIG. 6 illustrates a fragmentary cross-sectional view of the quad-cell 100 along cross section B-B′ in FIG. 5. The mirror image placement of the SRAM cells in the quad-cell 100 allows a source 137 of the second pull-down transistor PD2 to be placed next to a source 138 (not shown in FIG. 6 but shown in FIG. 7) of a pull-down transistor in an SRAM cell over the SRAM cell 10. In some embodiments represented in FIG. 7, the sources 137 and 138 are coupled to the Vss by way of not only the second common contact 132 but also through the backside joint contact 164. The additional electrical grounding provided by the backside joint contact 164 enables a higher saturation current for the second pull-down transistor PD2. Because the sources of the pass-gate transistors are not coupled to additional backside contacts, saturation currents of the pass-gate transistors are kept low. The greater saturation current of the pull-down transistors help keep a beta (β) ratio of the SRAM cell 10 greater than 1, which allows the SRAM cell 10 have good read stability. The lower saturation current of the pass-gate transistors help keep an alpha (α) ratio of the SRAM cell high, which allows the SRAM cell 10 to have good writability. The fragmentary cross-sectional view in FIG. 7 illustrates a gate isolation feature 121. Referring to FIG. 7, the gate isolation feature 121 isolates the gate structure 22 from a gate structure in a mirror image SRAM cell across the first mirror axis MA1. In some embodiments, the gate isolation feature 121 may include silicon nitride, silicon oxide, silicon oxynitride, silicon oxycarbonitride, silicon oxycarbide, silicon carbonitride, or a combination thereof. In one embodiment, the gate isolation feature 121 includes silicon nitride. The backside joint contact 164 may include titanium (Ti), tungsten (W), ruthenium (Ru), cobalt (Co), nickel (Ni), or a combination thereof.

FIG. 7 is fragmentary cross-sectional view of a backside joint contact 164 along cross section C-C′ in FIG. 5. As shown in FIG. 5, cross section C-C′ cuts through the SRAM cell 10 and a mirror image SRAM cell across the second mirror axis MA2. Referring to FIG. 7, cross section C-C′ cuts through gate structures 26 and 22 in the SRAM cell 10 as well as the counterpart gate structures in the mirror image SRAM cell across the second mirror axis MA2. FIG. 7 illustrates that the backside metal line 172 is disposed in a backside insulation layer 170. In some embodiments, the backside metal line 172 may include copper (Cu), cobalt (Co), aluminum (Al), nickel (Ni), or a combination thereof and the backside insulation layer 170 may include a low-k dielectric layer with a dielectric constant smaller than that of silicon dioxide (˜3.9). In some instances, the backside insulation layer 170 may include silicon oxide and may be porous. The backside joint contact 164 includes a bar portion 164B, a first via 164-1 extending continuously from the bar portion 164B, a second via 164-2 extending continuously from the bar portion 164B, and a middle protrusion 168 extending continuously from the bar portion 164B. The bar portion 164B is disposed in a hard mask layer 150. In some embodiments, the hard mask layer 150 includes silicon nitride. The first via 164-1 extends through an isolation feature 103 and gate spacers 111 to terminate in a source 137 the second pull-down transistor PD2. The second via 164-2 extends through the isolation feature 103 and the gate spacers 111 to terminate in a source 138 of a second pull-down transistor PD2 of an SRAM cell adjacent the SRAM cell 10. The isolation feature 103 is disposed between active region and may also be referred to as a shallow trench isolation (STI) feature 103. The isolation feature 103 is formed of an oxide-based material, such as silicon oxide, silicon oxynitride, fluorine-doped silicate glass (FSG), a low-k dielectric, or a combination thereof. The middle protrusion 168 is disposed between the first via 164-1 and the second via 164-2 along the X direction is formed when the gate isolation feature 121 is partially etched during the formation of the joint backside opening.

Reference is still made to FIG. 7. The first via 164-1 is electrically coupled to the source 137 by way of a silicide feature 166. Similar, the second via 164-1 is electrically coupled to the source 138 by way of the silicide feature 166. In some embodiments, the silicide feature 166 may include titanium silicide, cobalt silicide, or nickel silicide. A contact etch stop layer (CESL) 109 is deposited over the isolation feature 103, the gate spacers 111, and the sources 137 and 138. A first interlayer dielectric (ILD) layer 113 is formed over the CESL 109. A composition of the CESL 109 is different from a composition of the first ILD layer 113. Along the X direction, a thickness of the first ILD layer 113 is greater than a thickness of the CESL 109. An etch stop layer (ESL) 115 is formed over the first ILD layer 113. A second ILD layer 117 is disposed over the ESL 115. As shown in FIG. 7, because the first ILD layer 113 needs to accommodate the active region and/or the source/drain features, a thickness of the first ILD layer 113 is greater than a thickness of the second ILD layer 117 along the Z direction. The first ILD layer 113 and the second ILD layer 117 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The CESL 109 and the ESL 115 may include silicon nitride. Over the second common contact 132 and the second ILD layer lies a top ESL 133. A first intermetal dielectric (IMD) layer 135 is disposed over the top ESL 133. A second IMD layer 144 is disposed over the first IMD layer 135. An ESL 145 is disposed over the second IMD layer 144. A third IMD layer 147 is disposed over the ESL 145. A plurality of first frontside metal lines 143 are disposed in the second IMD layer 144. A first contact via 141 extends from one of the first frontside metal lines 143 to the second common contact 132. A second contact via 149 extends through the third IMD layer 147 and the ESL 145 to couple to one of the frontside metal lines 143. In the depicted embodiments, the top ESL 133 and the ESL 145 may include silicon nitride. The first IMD layer 135, the second IMD layer 144, and the third IMD layer 147 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The first contact via 141, the first frontside metal lines 143, and second contact via 149 may include copper (Cu), cobalt (Co), nickel (Ni), or a combination thereof.

The second common contact 132 is spaced apart from the second ILD layer 117, the ESL 115, the first ILD layer 113 by a liner 131. The liner 131 may include silicon nitride. A middle portion of the second common contact 132 extends downward into the gate isolation feature 121 such that the middle portion is disposed between the source 137 and the source 138 along the X direction. Along surfaces away from the gate isolation feature 121, the backside joint contact 164 is spaced apart from the isolation feature 103, the hard mask layer 150, and the gate spacer 111 by a liner 162. Due to an etch back step to be described in more detail below, a portion of the backside joint contact 164 around the protrusion 168 comes in contact with the isolation feature 103. Additionally, the protrusion 168 partially extends into and interfaces the gate isolation feature 121. In some embodiments, the liner 162 and the gate isolation feature 121 may include silicon nitride.

As shown in FIG. 7, when viewed along a lengthwise direction of the active regions (i.e., the Y direction), the bar portion 164B, the first via 164-1, the second via 164-2, and the protrusion 168 give the backside joint contact 164 a M-shape or a shape similar to the letter M. In other words, it can be said that the backside joint contact 164 is M-shaped.

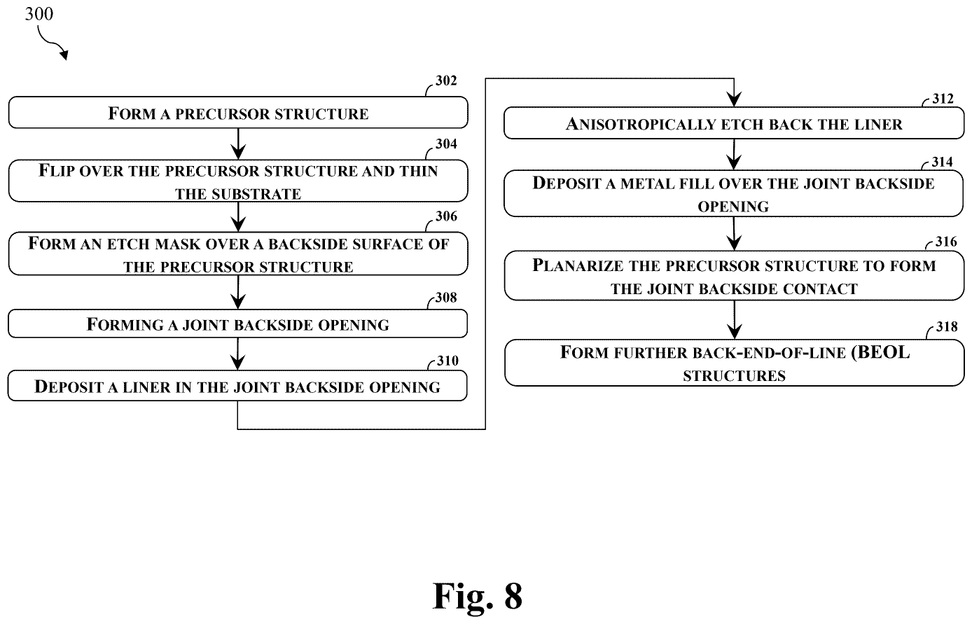

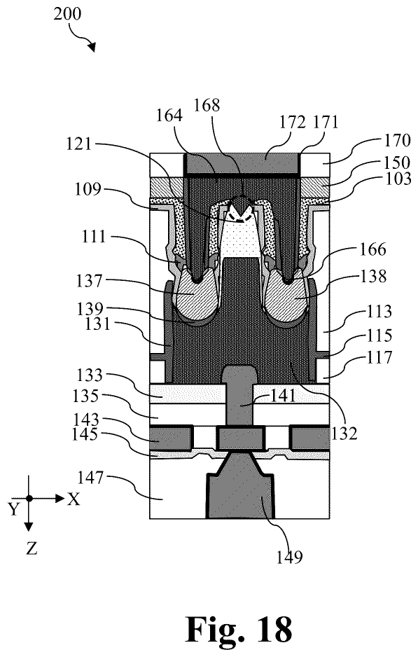

FIG. 8 is a flowchart illustrating method 300 of forming a backside joint contact similar to the backside joint contact 164 described above. Method 300 is merely an example and is not intended to limit the present disclosure to what is explicitly illustrated in method 300. Additional steps can be provided before, during and after method 300, and some steps described can be replaced, eliminated, or moved around for additional embodiments of the method. Not all steps are described herein in detail for reasons of simplicity. Method 300 is described below in conjunction with FIG. 2-19, which are fragmentary cross-sectional views and top views of a precursor structure 200 at different stages of fabrication according to various embodiments of method 300. Because the precursor structure 200 will be fabricated into a package structure, the precursor structure 200 may be referred to herein as a semiconductor structure 200 as the context requires. For avoidance of doubts, the X, Y and Z directions in figures in the present disclosure are perpendicular to one another. Throughout the present disclosure, unless expressly otherwise described, like reference numerals denote like features.

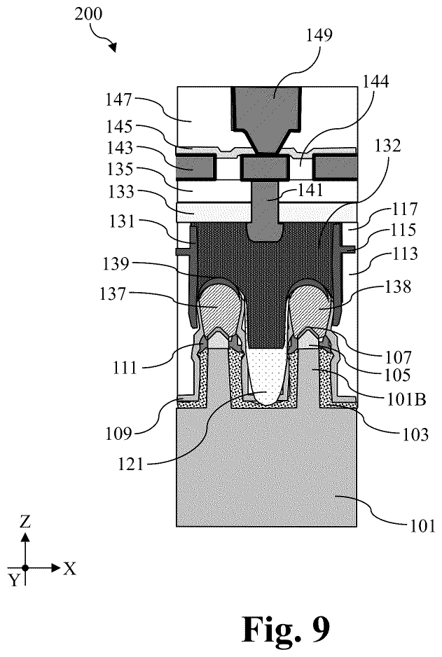

Referring to FIGS. 8 and 9, method 300 includes a block 302 where a precursor structure 200 is formed. FIG. 9 illustrates the precursor structure 200 that includes front-end-of-line (FEOL) structures, middle-end-of-line (MEOL) structures, and frontside back-end-of-line (BEOL) structures are formed over a substrate 101. In one embodiment, the substrate 101 may include silicon (Si). Alternatively or additionally, the substrate 101 may include another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. Alternatively, the substrate 101 is a semiconductor-on-insulator substrate, such as a silicon-on-insulator (SOI) substrate, a silicon germanium-on-insulator (SGOI) substrate, or a germanium-on-insulator (GOI) substrate.

At block 302, an epitaxial stack having alternating semiconductor layers is formed over the substrate 101. In some instances, the epitaxial stack may include a plurality of first semiconductor layers interleaved by a plurality of second semiconductor layers. The first semiconductor layers may include silicon (Si) and the second semiconductor layers may include silicon germanium (SiGe). While not explicitly shown in FIG. 9, the precursor structure 200 in FIG. 9 includes channel members (similar to the channel members 1080 shown in FIG. 4) released from the first semiconductor layers when the second semiconductor layers in the channel regions are selectively removed. A gate structure is formed to wrap around each of the channel members. End walls of the channel members interface the source 137 and the source 138. In the depicted embodiments where the transistors are GAA transistors, the epitaxial stack and a portion of the substrate 101 are patterned to form fin-shaped active regions. Each of the fin-shaped active regions may include a base fin 101B formed from the substrate 101 and a top portion formed from the epitaxial stack. FIG. 9 includes a cross-sectional view cutting across the source 137 and the source 138 in the source/drain region. As shown in FIG. 9, a buffer epitaxial layer 105 is disposed over a top surface of the base fins 101B and a bottom nitride layer 107 over the buffer epitaxial layer 105. In some embodiments, the buffer epitaxial layer 105 includes undoped silicon or undoped germanium and functions to prevent leakage into the substrate 101. The bottom nitride layer 107 includes silicon nitride and functions to control growth and stress of the source 137 or the source 138.

The source 137 and the source 138 may be epitaxially grown from the exposed end walls of the channel members. In some embodiments, the source 137 and the source 138 may include silicon doped with an n-type dopant, such as phosphorus (P) and arsenic (As). After the source 137 and the source 138 are formed, the CESL 109 is deposited over the isolation feature 103, the gate spacer 111, the source 137, and the source 138. The first ILD layer 113 is then formed over the CESL 109. After a planarization step, the ESL 115 is formed over the planar top surface of the first ILD layer 113 and a second ILD layer 117 is formed over the ESL 115. The gate isolation feature 121 is formed to divide a gate structure into two segments. As shown in FIG. 9, the gate isolation feature 121 also extends between the base fins 101B along the X direction. Using photolithography and etching techniques, a frontside contact opening is formed over the source 137 and the source 138. After formation of a liner 131, a metal fill 132 is deposited over the frontside contact opening and a planarization process is performed to form the second common contact 132. It is noted that the reference numeral 132 is used to denote both the metal fill and the second common contact formed from the metal fill. The second common contact 132 is considered a portion of the MEOL structures. Subsequently, frontside BEOL structures are formed over the second common contact 132 and the second ILD layer 117. Such frontside BEOL structures may the top ESL 133, the first intermetal dielectric (IMD) layer 135 over the top ESL 133, the second IMD layer 144 over the first IMD layer 135, the ESL 145 over the second IMD layer 144, the third IMD layer 147 over the ESL 145. Such frontside BEOL structures may also include a plurality of first frontside metal lines 143 disposed in the second IMD layer 144, the first contact via 141 extending between the first frontside metal lines 143 and the second common contact 132, the second contact via 149 extending through the third IMD layer 147 and the ESL 145. Compositions of these BEOL structures have been described above and will not be repeated here for brevity.

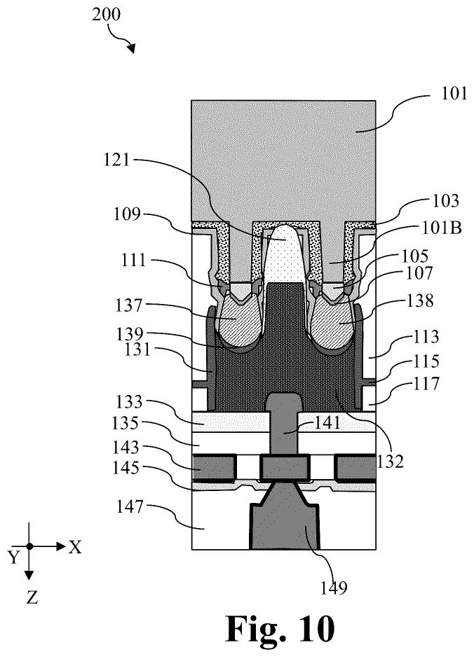

Referring to FIGS. 8, 10 and 11, method 300 includes a block 304 where the precursor structure 200 is flipped over and the substrate 101 is thinned. As shown in FIG. 10, the precursor structure 200 is flipped upside down at block 304. A combination of grinding and planarization processes are then performed to thin down the substrate 101 to expose the isolation feature 103 and the base fin 101B. The thinning at block 304 forms a planar backside surface 202 that includes bottom surfaces of the isolation feature 103 and the base fin 101B. In the depicted embodiments, the thinning at block 304 does not expose the gate isolation feature 121. In some alternative embodiments, the thinning at block 304 may expose a bottom portion of the gate isolation feature 121.

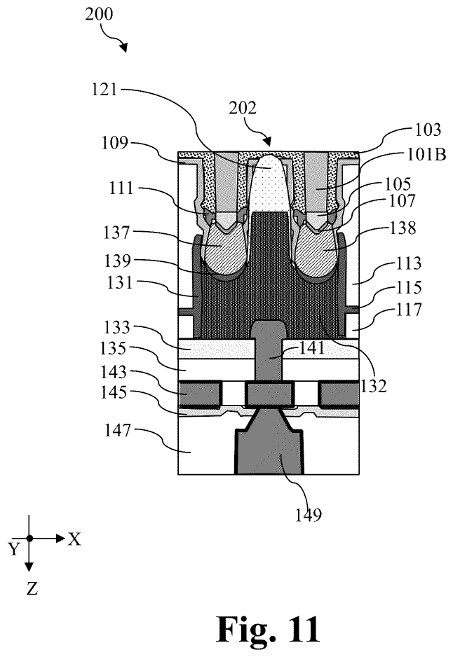

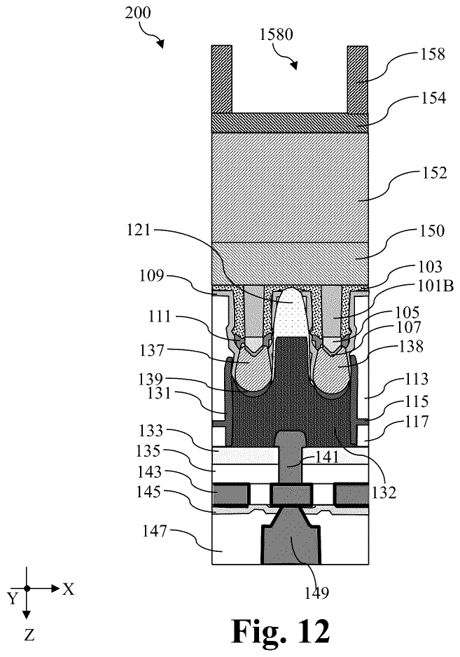

Referring to FIGS. 8 and 12, method 300 includes a block 306 where an etch mask is formed over a backside surface 202 (shown in FIG. 11) of the precursor structure 200. At block 306, a hard mask layer 150 is deposited over the backside surface 202 using chemical vapor deposition (CVD). Then a bottom antireflective coating (BARC) layer 152 is deposited over the hard mask layer 150 using flowable CVD (FCVD) or spin-on coating. A middle layer 154 is deposited over the BARC layer 152 using CVD, FCVD, or spin-on coating. In some embodiments, the middle layer 154 may include a silicon-containing inorganic polymer or silicon oxide (e.g., spin-on glass (SOG). A photoresist layer 158 is then deposited over the middle layer 154. The BARC layer 152, the middle layer 154 and the photoresist layer 158 may be collectively referred to as a tri-layer photoresist. Photolithography and etching processes are then performed to pattern the photoresist layer 158 to form a patterned photoresist layer 158. As shown in FIG. 12, the patterned photoresist layer 158 includes an opening 1580. The patterned photoresist layer 158 is going to be applied as an etch mask in subsequent operations.

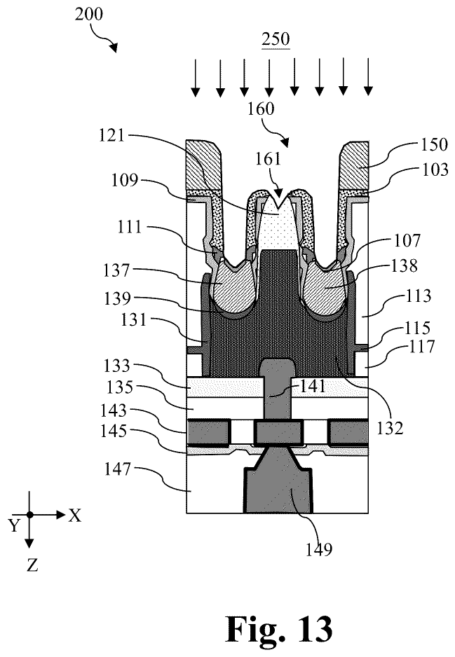

Referring to FIGS. 8 and 13, method 300 includes a block 308 where a joint backside opening 160 is formed. At block 308, an etch process 250 is performed to etch the precursor structure 200 using the patterned photoresist layer 158 as the etch mask. The etch process 250 is a dry etch process that etches silicon, silicon nitride, and silicon oxide at different rates. The etch process 250 etches silicon at a first rate, etches silicon nitride at a second rate, and etches silicon oxide at a third rate. In the depicted embodiments, the first rate is greater than the second rate and the second rate is greater than the third rate. This etching rate arrangement of the etch process 250 is not trivial. As shown in FIGS. 12 and 13, the etch process 250 needs to etch through the base fins 101B to at least reach the bottom nitride layer 107 while sidewalls of the base fins 101B are covered by the isolation feature 103. It means that the etch process 250 is intended to etch the base fins 101B and stop at the bottom nitride layer 107, without substantially damaging the isolation feature 103 and the hard mask layer 150. In the depicted embodiments, the base fins 101B include silicon (Si), the isolation feature 103 includes silicon oxide, and the hard mask layer 150 and the bottom nitride layer 107 includes silicon nitride. In some embodiments, the etch process 250 may include use of a fluorine-containing gas (e.g., carbon tetrafluoride (CF₄), nitrogen trifluoride (NF₃), chlorine trifluoride (ClF₃), or sulfur hexafluoride (SF₆)), oxygen (O₂), or hydrogen (H₂). In some embodiments illustrated in FIG. 13, the etch process 250 breaches the isolation feature 103 over the gate isolation feature 121 and recesses the gate isolation feature 121. As shown in FIG. 13, a tapered recess 161 may be formed in the gate isolation feature 121.

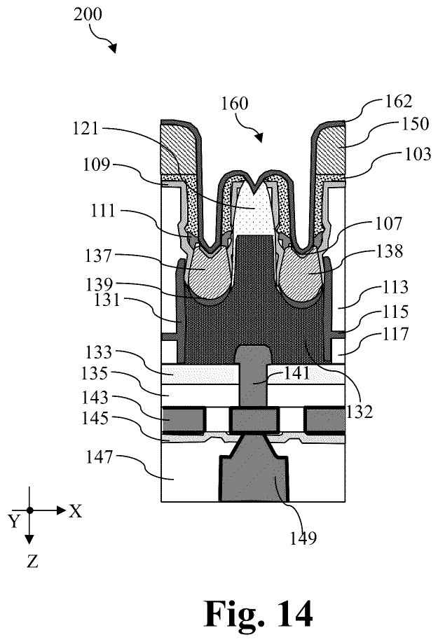

Referring to FIGS. 8 and 14, method 300 includes a block 310 where a liner 162 is deposited in the joint backside opening 160. In some embodiments, the liner 162 may include silicon nitride and may be deposited using atomic layer deposition (ALD), CVD, or plasma enhanced CVD (PECVD). As shown in FIG. 14, the liner 162 is conformally deposited over the joint backside opening 160. In the depicted embodiment, the liner 162 interfaces the hard mask layer 150, the isolation feature 103, the bottom nitride layer 107, the gate spacer 111, and the gate isolation feature 121.

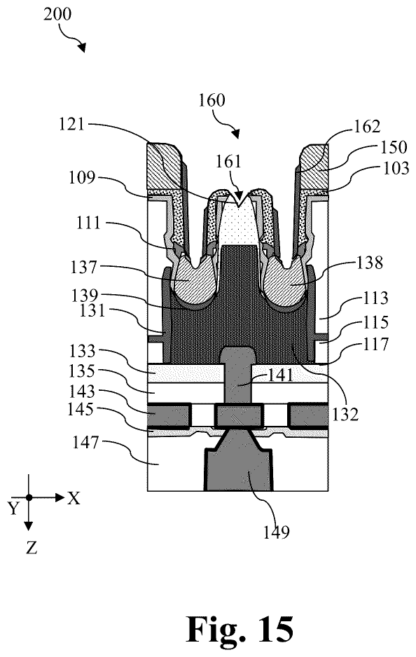

Referring to FIGS. 8 and 15, method 300 includes a block 312 where the liner 162 is anisotropically etched. At block 310, the source 137 and the source 138 are not exposed in the joint backside opening 160. The anisotropic etch at block 312 is performed to etch through the liner 162 and the leftover bottom nitride layer 107 to expose the source 137 and the source 138. In some embodiments, the anisotropic etch at block 312 may include use of a fluorine-containing gas (e.g., carbon tetrafluoride (CF₄), nitrogen trifluoride (NF₃), chlorine trifluoride (ClF₃), or sulfur hexafluoride (SF₆)) but is performed at lower temperature in order to achieve greater directivity. As shown in FIG. 15, upon conclusion of the operations a block 312, the source 137 and the source 138 are exposed in the joint backside opening 160 while sidewalls of the joint backside opening 160 remain covered by the liner 162. That is, the liner 162 on the top-facing surfaces are removed. In FIG. 15, the top facing surfaces may include top surfaces of the hard mask layer 150, the top surfaces of the isolation feature 103 around the tapered recess 161, and the surfaces of the tapered recess 161.

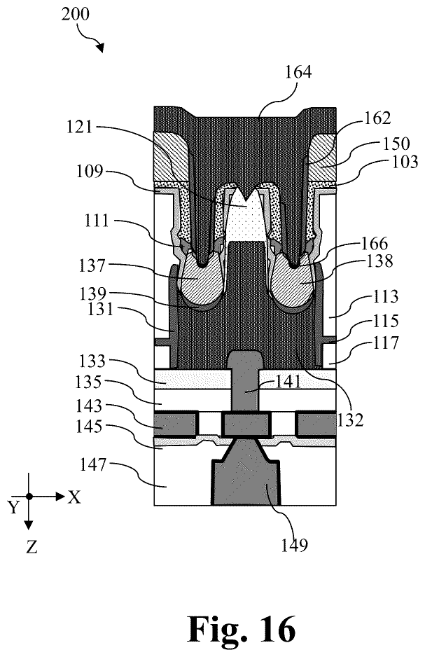

Referring to FIGS. 8 and 16, method 300 includes a block 314 where a metal fill 164 is deposited over the joint backside opening 160. In some embodiments, the metal fill 164 may include titanium (Ti), tungsten (W), ruthenium (Ru), cobalt (Co), nickel (Ni), or a combination thereof. In an example process, titanium is first deposited over the joint backside opening 160 to interface the source 137 and the source 138. An anneal process is then performed to promote reaction between titanium and silicon in the sources 137 and 138 to form a silicide feature 166. After the formation of the silicide feature 166, a selective etch process may be performed to remove titanium that has not reacted with silicon. In some alternative embodiments, the excess titanium is not removed. The metal fill 164 is then deposited over the joint backside opening 160 using physical vapor deposition (PVD) or CVD.

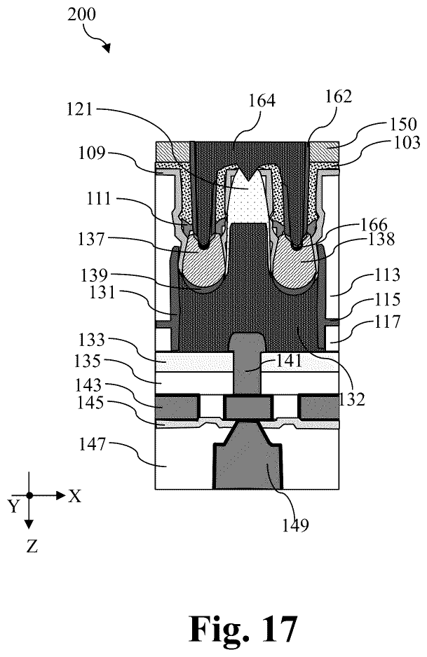

Referring to FIGS. 8 and 17, method 300 includes a block 316 where the precursor structure 200 is planarized to form the backside joint contact 164. At block 316, a planarization process, such as a chemical mechanical polishing (CMP) process, is performed to remove the excess metal fill 164 over the hard mask layer 150 to form the backside joint contact 164. It is noted that the reference numeral 164 is used to denote both the metal fill and the backside joint contact. As shown in FIG. 17, the hard mask layer 150, the liner 162, and the backside joint contact 164 are exposed in the newly formed planar backside surface. Upon conclusion of the operations at block 316, the backside joint contact 164 is substantially formed. As described above in conjunction with FIG. 7, the backside joint contact 164 includes a bar portion 164B, a first via 164-1 extending continuously from the bar portion 164B, a second via 164-2 extending continuously from the bar portion 164B, and a middle protrusion 168 extending continuously from the bar portion 164B. When viewed along a lengthwise direction of the active regions (i.e., the Y direction), the bar portion 164B, the first via 164-1, the second via 164-2, and the protrusion 168 give the backside joint contact 164 a M-shape or a shape similar to the letter M. In other words, it can be said that the backside joint contact 164 is M-shaped. The middle protrusion 168 is formed when the metal fill 164 fills the tapered recess 161 shown in FIG. 15. In terms of electrical conductivity, an electrical conductivity of the backside joint contact 164 is greater than that of the silicide feature 166, which is more electrically conductive than the source 137 or the source 138.

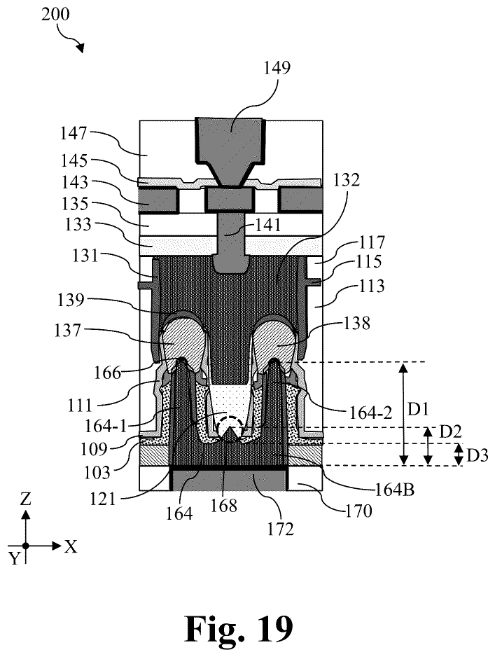

Referring to FIGS. 8, 18 and 19, method 300 includes a block 318 where further back-end-of-line (BEOL) structures are formed. Such further BEOL structures include a backside insulation layer 170 and a backside metal line 172 disposed in the backside insulation layer 170. In some embodiments, the backside insulation layer 170 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The backside insulation layer 170 may be deposited using FCVD or spin-on coating. After deposition of the backside insulation layer 170, a backside line trench is formed in the backside insulation layer 170 to expose a bottom surface of the bar portion 164B of the backside joint contact 164. A barrier layer 171 and a metal fill are then deposited over the backside line trench. A planarization process, such as a CMP process, is then performed to remove the excess metal fill and the barrier layer 171 to form the backside metal line 172. In some embodiments, the barrier layer 171 may include titanium nitride, tantalum nitride, or tungsten nitride. The metal fill for the backside metal line 172 may include copper (Cu), cobalt (Co), aluminum (Al), nickel (Ni), or a combination thereof. FIG. 19 illustrates a fragmentary cross-sectional view of the precursor structure 200 when the backside interconnect structure is at the bottom and the frontside interconnect structure is on the top. In the orientation shown in FIG. 19, the source 137 is disposed over the first via 164-1 with the silicide feature 166 at the interface and the source 138 is disposed over the second via 164-2 with the silicide feature 166 at the interface. The second common contact 132 is a frontside source/drain contact and the backside joint contact 164 is a backside source/drain contact.

Reference is still made to FIG. 19. In the depicted embodiments, as measured from an interface between the bar portion 164B and the backside metal line 172, the first via 164-1 and the second via 164-2 have a first depth D1, the middle protrusion 168 has a second depth D2, and the bar portion 164B has a third depth D3. The first depth D1 is greater than the second depth D2 and the second depth D2 is greater than the third depth D3. In some instances, a ratio of the second depth D2 to the first depth D1 is between about 0.3 and about 0.8. Because the etch process 250 etches silicon nitride faster than it does silicon oxide, a ratio of the third depth D3 and second depth D2 is between about 0.3 and about 0.8. Because the etch process 250 etches silicon faster than it does silicon oxide, a ratio of the third depth D3 and first depth D1 is between about 0.15 and about 0.5.

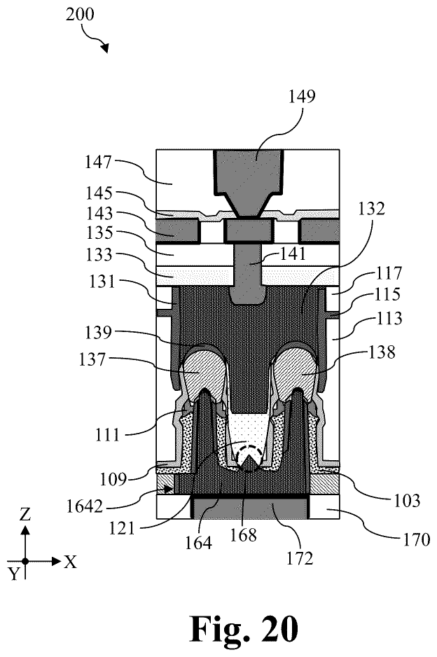

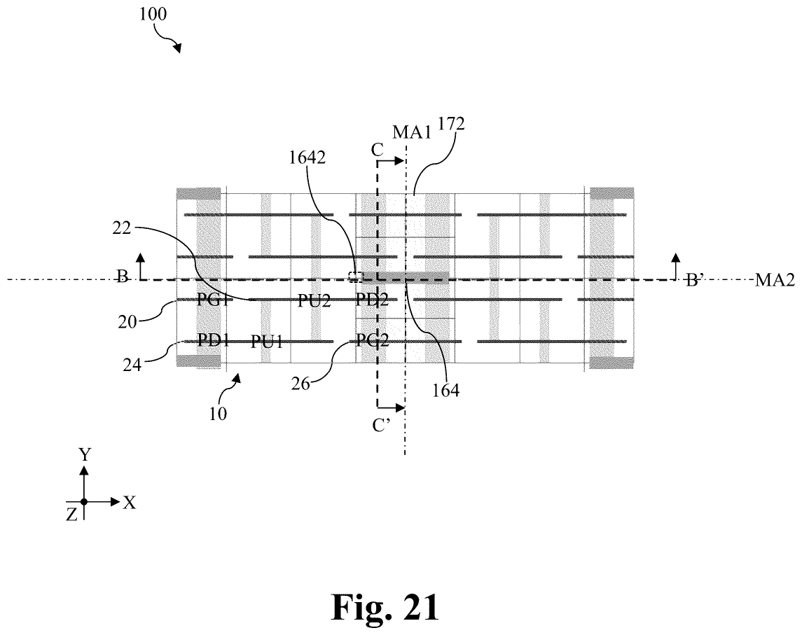

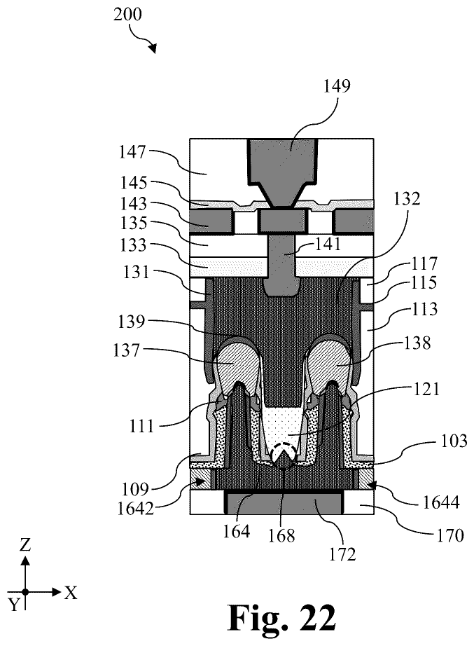

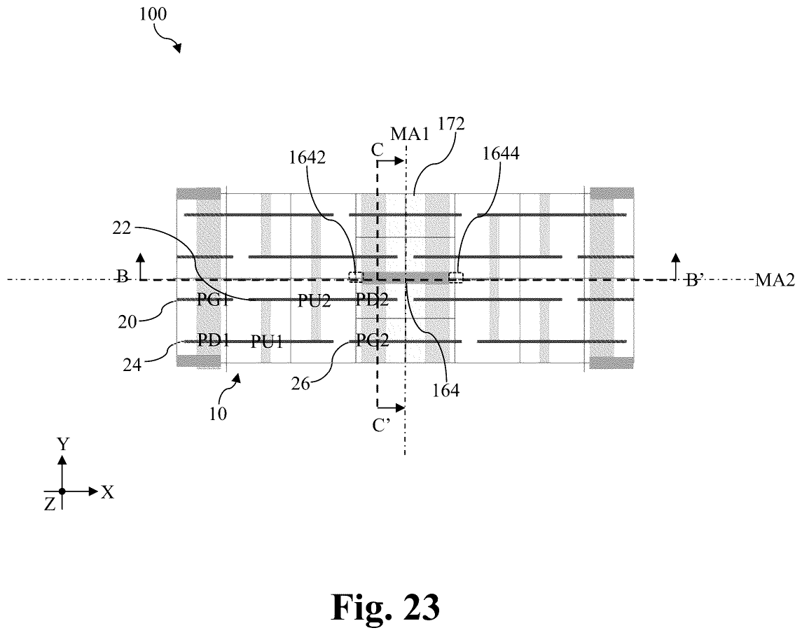

FIGS. 20-25 illustrate alternative structures of the backside joint contact 164 that may be formed using method 300 described above. FIGS. 20-23 illustrate alternative embodiments where the backside joint contact 164 is not completely coterminous with the backside metal line 172 along the X direction and at least a jut portion of the backside joint contact 164 overhangs the backside metal line 172. That is, along the X direction, a dimension of the bar portion 164B is greater than a dimension of the backside metal line 172. For example, FIG. 20 illustrates a backside joint contact 164 that includes a first jut portion 1642 that does not vertically overlap with the backside metal line 172. Instead, the first jut portion 1642 extends between the isolation feature 103 and the backside insulation layer 170. A sidewall of the first jut portion 1642 is spaced apart from the backside insulation layer 170 by the liner 162. The first jut portion 1642, shown in a dotted rectangle in the top view shown in FIG. 21, extends beyond the edge of the backside metal line 172 along the X direction. For another example, FIG. 22 illustrates a backside joint contact 164 that includes a first jut portion 1642 and a second jut portion 1644 that do not vertically overlap with the backside metal line 172. Instead, each of the first jut portion 1642 and the second jut portion 1644 extends between the isolation feature 103 and the backside insulation layer 170 along the Z direction (i.e., vertical direction). A sidewall of the first jut portion 1642 or the second jut portion 1644 is spaced apart from the backside insulation layer 170 by the liner 162. The first jut portion 1642 and the second jut portion 1644, shown in a dotted rectangle in the top view shown in FIG. 23, extend beyond the edge of the backside metal line 172 along the X direction.

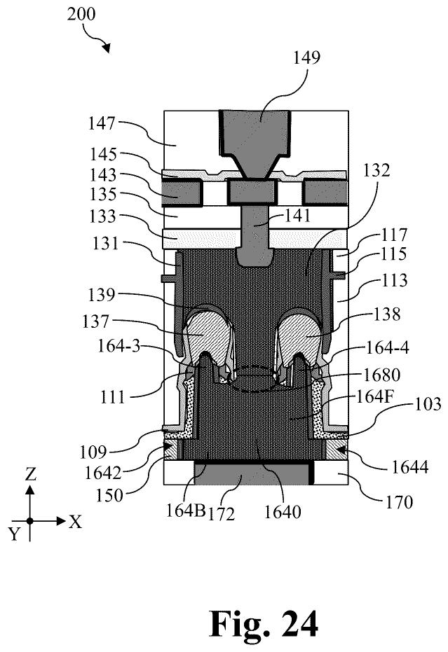

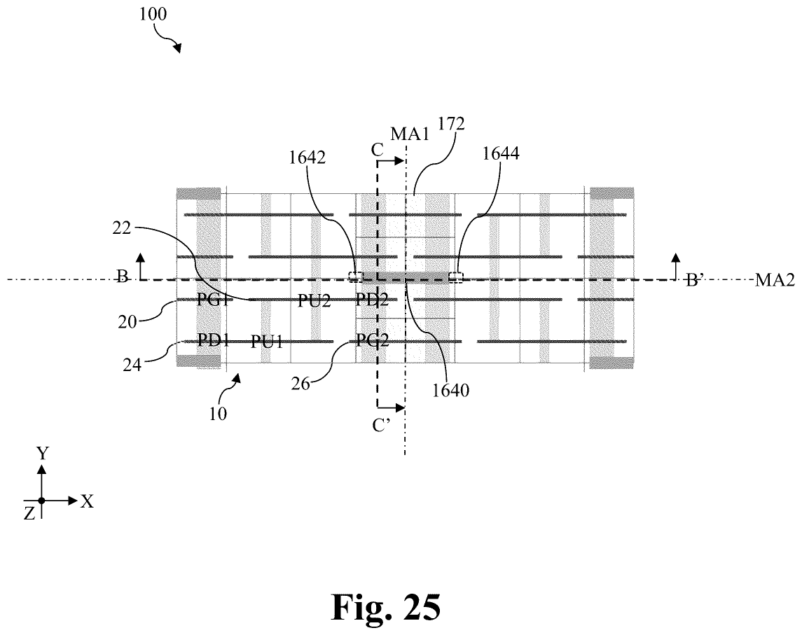

FIG. 24 illustrates an alternative embodiment where a through backside joint contact 1640 extends through the gate isolation feature 121 (shown in FIG. 19) to merge with or interface the second common contact 132. In this alternative embodiment, the through backside joint contact 1640 is still arguably M-shaped but has a different profile than the backside joint contact 164 illustrated in FIGS. 19, 20, or 22. As shown in FIG. 24, the through backside joint contact 1640 includes a bar portion 164B disposed in the hard mask layer 150, a fin portion 164F continuously extend from the bar portion 164B, a first short fin 164-3 extending from the fin portion 164F, a second short fin 164-4 extending from the fin portion 164F, and a middle mesa 1680 disposed on the fin portion 164F. The middle mesa 1680 is disposed between the first short fin 164-3 and the second short fin 164-4 along the X direction. The bar portion 164B, the first short fin 164-3, the second short fin 164-4, and the middle mesa 1680 gives the through backside joint contact 1640 an M shape. In some implementations, the through backside joint contact 1640 includes a first jut portion 1642 and the second jut portion 1644 overhanging the backside metal line 172. The first jut portion 1642 and the second jut portion 1644, shown in a dotted rectangle in the top view shown in FIG. 25, extend beyond the edge of the backside metal line 172 along the X direction.

In one example aspect, the present disclosure provides a semiconductor structure. The semiconductor structure includes a backside metal line disposed in a backside insulation layer, a backside contact structure having a bar portion disposed on the backside metal line, a first via extending from the bar portion, a second via extending from the bar portion, and a protrusion disposed between the first via and the second via, a first source/drain feature over the first via, a second source/drain feature over the second via, a gate isolation feature disposed between the first via and the second via, and a silicide feature disposed between the first via and the first source/drain feature. The protrusion extends into the gate isolation feature. An electrical conductivity of the first via is greater than an electricity of the silicide feature.

In some embodiments, the semiconductor structure further includes a frontside contact feature disposed over the first source/drain feature and the second source/drain feature. A portion of the frontside contact feature extends between the first source/drain feature and the second source/drain feature to interface the gate isolation feature. In some implementations, a portion of the bar portion overhangs the backside metal line. In some embodiments, the bar portion, the first via, the second via, and the protrusion of the backside contact structure form an M shape. In some embodiments, the semiconductor structure further includes an isolation feature extending along sidewalls of the first via and sidewalls of the second via. A portion of the isolation feature is spaced apart from the first via by a liner and another portion of the isolation feature interfaces the first via. In some instances, the isolation feature is formed of an oxide-based material. In some embodiments, a portion of the bar portion is disposed between the backside insulation layer and the isolation feature. In some implementations, the backside insulation layer is spaced apart from the isolation feature by a hard mask layer. In some instances, a sidewall of the bar portion is spaced apart from the hard mask layer by the liner. In some embodiments, the hard mask layer includes silicon nitride.

Another aspect of the present disclosure pertains to a semiconductor structure. The semiconductor structure includes a backside insulation layer, a backside metal line disposed in the backside insulation layer, a hard mask layer over the backside insulation layer, a backside contact structure disposed over the backside metal line and including a bar portion disposed in the hard mask layer, a first via extending from the bar portion, a second via extending from the bar portion, and a protrusion disposed between the first via and the second via along a direction, a first source/drain feature disposed over the first via, a second source/drain feature disposed over the second via, a gate isolation feature disposed between the first source/drain feature and the second source/drain feature along the direction, an isolation feature extending along sidewalls of the first via and sidewalls of the second via, a contact etch stop layer (CESL) over the isolation feature, and an interlayer dielectric (ILD) layer over the CESL. The isolation feature includes an oxide-based material. A composition of the CESL is different from a composition of the ILD layer. The bar portion, the first via, the second via, and the protrusion of the backside contact structure form an M shape.

In some embodiments, the protrusion partially extends into the gate isolation feature. In some implementations, the first via is electrically coupled to the first source/drain feature by way of a first silicide feature and the second via is electrically coupled to the second source/drain feature by way of a second silicide feature. In some embodiments, the semiconductor structure further includes a frontside contact feature disposed over the first source/drain feature and the second source/drain feature. A portion of the frontside contact feature extends between the first source/drain feature and the second source/drain feature along the direction to interface the gate isolation feature. In some implementations, a portion of the bar portion overhangs the backside metal line.

Yet another aspect of the present disclosure pertains to a method. The method includes providing a precursor structure that includes a first source/drain feature and a second source/drain feature over a frontside source/drain contact, a first base fin over the first source/drain feature, a second base fin over the second source/drain feature, an isolation feature disposed between the first base fin and the second base fin and extending along sidewalls of the first base fin and the second base fin, and a gate isolation feature disposed between the first base fin and the second base fin, depositing a hard mask layer over the isolation feature, the first base fin and the second base fin, forming a patterned photoresist layer over the hard mask layer, etching the precursor structure and the hard mask layer using the patterned photoresist layer as an etch mask to form a joint backside opening that exposes the isolation feature and the gate isolation feature, depositing a liner over the joint backside opening, after the depositing of the liner, performing an anisotropic etch to expose the first source/drain feature and the second source/drain feature, depositing a metal fill in the joint backside opening, and planarizing the metal fill to expose the hard mask layer and to form a backside joint contact. The isolation feature includes an oxide-based material. A silicide layer is disposed between the first source/drain feature and the frontside source/drain contact. An electrical conductivity of the frontside source/drain contact is greater than an electrical conductivity of the silicide layer.

In some embodiments, the etching of the precursor structure etches silicon at a first rate, etches silicon nitride at a second rate, and etches silicon oxide at a third rate. The first rate is greater than the second rate and the second rate is greater than the third rate. In some implementations, the backside joint contact is M-shaped. In some embodiments, the hard mask layer includes silicon nitride. In some embodiments, the etching of the precursor structure forms a recess in the gate isolation feature.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed IS:

1. A semiconductor structure, comprising:
a backside metal line disposed in a backside insulation layer;
a backside contact structure comprising:
a bar portion disposed on the backside metal line;
a first via extending from the bar portion,
a second via extending from the bar portion, and
a protrusion disposed between the first via and the second via;
a first source/drain feature over the first via;
a second source/drain feature over the second via;
a gate isolation feature disposed between the first via and the second via; and
a silicide feature disposed between the first via and the first source/drain feature,
wherein the protrusion extends into the gate isolation feature,
wherein an electrical conductivity of the first via is greater than an electricity of the silicide feature.

2. The semiconductor structure of claim 1, further comprising:
a frontside contact feature disposed over the first source/drain feature and the second source/drain feature,
wherein a portion of the frontside contact feature extends between the first source/drain feature and the second source/drain feature to interface the gate isolation feature.

3. The semiconductor structure of claim 1, wherein a portion of the bar portion overhangs the backside metal line.

4. The semiconductor structure of claim 1, wherein the bar portion, the first via, the second via, and the protrusion of the backside contact structure form an M shape.

5. The semiconductor structure of claim 1, further comprising:
an isolation feature extending along sidewalls of the first via and sidewalls of the second via,
wherein a portion of the isolation feature is spaced apart from the first via by a liner,
wherein another portion of the isolation feature interfaces the first via.

6. The semiconductor structure of claim 5, wherein the isolation feature is formed of an oxide-based material.

7. The semiconductor structure of claim 5, wherein a portion of the bar portion is disposed between the backside insulation layer and the isolation feature.

8. The semiconductor structure of claim 5, wherein the backside insulation layer is spaced apart from the isolation feature by a hard mask layer.

9. The semiconductor structure of claim 8, wherein a sidewall of the bar portion is spaced apart from the hard mask layer by the liner.

10. The semiconductor structure of claim 8, wherein the hard mask layer comprises silicon nitride.

11. A semiconductor structure, comprising:
a backside insulation layer;
a backside metal line disposed in the backside insulation layer;
a hard mask layer over the backside insulation layer;
a backside contact structure disposed over the backside metal line, the backside contact structure comprising:
a bar portion disposed in the hard mask layer,
a first via extending from the bar portion,
a second via extending from the bar portion, and
a protrusion disposed between the first via and the second via along a direction;
a first source/drain feature disposed over the first via;
a second source/drain feature disposed over the second via;
a gate isolation feature disposed between the first source/drain feature and the second source/drain feature along the direction;
an isolation feature extending along sidewalls of the first via and sidewalls of the second via;
a contact etch stop layer (CESL) over the isolation feature; and
an interlayer dielectric (ILD) layer over the CESL,
wherein the isolation feature comprises an oxide-based material,
wherein a composition of the CESL is different from a composition of the ILD layer,
wherein the bar portion, the first via, the second via, and the protrusion of the backside contact structure form an M shape.

12. The semiconductor structure of claim 11, wherein the protrusion partially extends into the gate isolation feature.

13. The semiconductor structure of claim 11,
wherein the first via is electrically coupled to the first source/drain feature by way of a first silicide feature,
wherein the second via is electrically coupled to the second source/drain feature by way of a second silicide feature.

14. The semiconductor structure of claim 11, further comprising:
a frontside contact feature disposed over the first source/drain feature and the second source/drain feature,
wherein a portion of the frontside contact feature extends between the first source/drain feature and the second source/drain feature along the direction to interface the gate isolation feature.

15. The semiconductor structure of claim 11, wherein a portion of the bar portion overhangs the backside metal line.

16. A method, comprising:
providing a precursor structure comprising:
a first source/drain feature and a second source/drain feature over a frontside source/drain contact,
a first base fin over the first source/drain feature,
a second base fin over the second source/drain feature,
an isolation feature disposed between the first base fin and the second base fin and extending along sidewalls of the first base fin and the second base fin, and
a gate isolation feature disposed between the first base fin and the second base fin;
depositing a hard mask layer over the isolation feature, the first base fin and the second base fin;
forming a patterned photoresist layer over the hard mask layer;
etching the precursor structure and the hard mask layer using the patterned photoresist layer as an etch mask to form a joint backside opening that exposes the isolation feature and the gate isolation feature;
depositing a liner over the joint backside opening;
after the depositing of the liner, performing an anisotropic etch to expose the first source/drain feature and the second source/drain feature;
depositing a metal fill in the joint backside opening; and
planarizing the metal fill to expose the hard mask layer and to form a backside joint contact,
wherein the isolation feature comprises an oxide-based material,
wherein a silicide layer is disposed between the first source/drain feature and the frontside source/drain contact,
wherein an electrical conductivity of the frontside source/drain contact is greater than an electrical conductivity of the silicide layer.

17. The method of claim 16,
wherein the etching of the precursor structure etches silicon at a first rate, etches silicon nitride at a second rate, and etches silicon oxide at a third rate,
wherein the first rate is greater than the second rate,
wherein the second rate is greater than the third rate.

18. The method of claim 16, wherein the backside joint contact is M-shaped.

19. The method of claim 16, wherein the hard mask layer comprises silicon nitride.

20. The method of claim 16, wherein the etching of the precursor structure forms a recess in the gate isolation feature.
